(19) United States
(12) Patent Application Publication
(10) Pub. No.: US 2025/0313941 A1
(43) Pub. Date: Oct. 9, 2025

(54) METHOD FOR COATING A SUBSTRATE

(71) Applicant: Carl Zeiss SMT GmbH, Oberkochen (DE)

(72) Inventors: Martin Hermann, Heidenheim (DE); Jeffrey Erxmeyer, Oberkochen (DE)

(21) Appl. No.: 19/170,372

(22) Filed: Apr. 4, 2025

(30) Foreign Application Priority Data
Apr. 9, 2024 (DE) 102024203201.8

(51) Int. Cl. C23C 14/30; C23C 14/08; G02B 1/10

(52) U.S. Cl. CPC C23C 14/30; C23C 14/08; G02B 1/10

(57) ABSTRACT

Disclosed is a method for coating a substrate with at least one coating comprising at least one coating material, the coating material being deposited on the substrate or on a partial coating applied on the substrate, wherein electrically neutral particles are made available to assist the deposition. Also disclosed is a resulting optical element comprising the substrate and coating.

### CROSS REFERENCE TO RELATED APPLICATIONS

This application claims priority under 35 U.S.C. § 119 to German Patent Application No. 10 2024 203 201.8, filed on Apr. 9, 2024. The entire disclosure of this application is incorporated by reference herein.

### TECHNICAL FIELD

The present invention relates to methods for coating a substrate with at least one coating comprising at least one coating material, the coating material being deposited on the substrate or on a partial coating applied on the substrate, and to optical elements produced using these methods.

### BACKGROUND

Particularly in the relatively short-wave ultraviolet wavelength range between approximately 150 nm and 260 nm, also called DUV (deep ultraviolet) radiation, optical elements are used which have an optical coating and/or substrate with poor electrical conductivity compared with metallic materials. In regard to the service life of the optical elements, it is advantageous if the optical coatings are minimally porous. In order to reduce the porosity thereof during deposition, it is possible for deposition to take place with ion assistance, as disclosed for example in DE 10 2005 017 742 A1. On account of the ion assistance, a poorly electrically conductive substrate or the coating applied thereto can become electrically charged within a very short time, in particular shorter than 1 ms. Customary substrates are typically glasses such as, for instance, fused silica or calcium fluoride. However, even substrates with nominally good electrical conductivity, such as e.g. metals, may be affected by this if they are provided with an electrically non-conductive coating, which can in turn become electrically charged. Particularly in the case of relatively large optical elements, the charging can result in fluctuating conditions both possibly from individual layer to individual layer and over the area to be coated during layer deposition, which in turn influence the optical properties of the growing layer, for example.

### SUMMARY

Embodiments disclosed herein demonstrate a method in which the coating conditions remain substantially constant during layer deposition.

In certain embodiments, this object is achieved by a method for coating a substrate with at least one optically effective coating comprising at least one coating material, the coating material being deposited on the substrate or on a partial coating applied on the substrate, and electrically neutral particles being made available to assist the deposition.

It has been found that assistance of layer deposition need not necessarily be carried out using charged particles, but rather can also be effected using neutral particles. Particularly in the case of substrates and coatings with relatively low conductivity, this has the advantage that charging of the substrate undergoing the coating process can be avoided and, as a result, the coating conditions remain substantially constant during layer deposition. Constant coating conditions can be afforded in a spatially constant manner over the substrate surface to be coated and/or in a temporally constant manner during the deposition of a layer. If there is more than one layer, constant coating conditions can also concern readily reproducible depositions from individual layer to individual layer. The resulting coating can be, inter alia, an optical coating or else a protective coating or a coating to withstand mechanical stresses in the optical element.

Advantageously, neutral particles having an energy of between 50 eV and 500 eV, preferably 75 eV and 300 eV, particularly preferably 100 eV and 200 eV, are made available. What can be achieved by this means is that, firstly, the deposited layer is effectively densified and, secondly, the layer structure is not influenced too much or sputter effects on the layer itself or on surfaces in the vicinity thereof remain negligible or are even entirely avoided.

Preferably, neutral particles are made available at an angle of incidence of up to 60° with respect to the surface normal, preferably up to 45°, particularly preferably up to 30°. What can be achieved by this means, too, is that, firstly, the deposited layer is effectively densified and, secondly, the layer structure is not influenced too much or sputter effects on the layer itself or on surfaces in the vicinity thereof remain negligible or are even entirely avoided.

It should be pointed out that particularly preferably depending on the combination of coating material and the neutral particles used for assistance, angles of incidence of the particles and the energy thereof are coordinated with one another.

Preferably, one or more noble gases are used as assistance gas. Since noble gases are inert, this makes it possible to ensure that the layer to be deposited is not contaminated by unwanted chemical reactions.

It has proved to be advantageous if at least one volatile element of the material of the coating to be applied is added to the assistance gas in order to additionally promote the growth of a desired layer.

In one preferred variant-for instance in order to produce a reflective optical element-an electrically conductive substrate, for example a metallic or metallically coated substrate, is coated and a voltage is applied to the substrate. In this way, an electric field can be formed such that possible charged particles that would be present in the stream of neutral particles are deflected from the substrate to be coated.

In a further preferred variant, a poorly conductive substrate, for example composed of a fluoride crystal, in order to produce a transmissive optical element, is coated and an electrode is arranged on the opposite side of the substrate with respect to the particle flow. In this way, an electric field can be formed such that possible charged particles that would be present in the stream of neutral particles are deflected from the substrate to be coated. This procedure is particularly advantageous for large-format substrates.

In a further preferred variant, on the side of the substrate facing the particle flow, at least one electrode is arranged in the direction of the particle flow. In this way, possible charged particles can be deflected before they are incident on the substrate surface, with the result that instead they are incident on the electrode. Particularly preferably, at least two electrodes are provided and subjected to opposite potentials, such that both negatively and positively charged particles can be removed from the stream of neutral particles.

In a further aspect, the object is achieved by a method for coating a substrate with at least one coating comprising at least one coating material, the coating material being deposited on the substrate or on a partial coating applied on the substrate, and the substrate being impinged on by electrons by virtue of the fact that a component is used which comprises a filament arranged in a housing, and also, at an opening provided on the housing, at least one grid having a potential difference relative to the filament.

Overall, it has proved to be advantageous to carry out the deposition by means of electron beam evaporation or thermal evaporation. Both kinds of coating are a tried and tested method even for poorly conductive to non-conductive coating materials. Moreover, the particle-assisted deposition is particularly effective for both methods.

Furthermore, the object is achieved by an optical element having at least one layer which was applied as explained above. By virtue of the fact that the coating takes place with assistance of electrically neutral particles or with impingement of electrons, unwanted charging effects at the optical element being produced can be counteracted and more constant coating parameters can be ensured, which can result in more optical elements having a coating within the tolerance ranges for the optical properties desired in each case.

In preferred embodiments, at least one oxidic layer was applied in this way. Particularly for optical elements for the UV wavelength range, a multiplicity of oxidic layer materials are used, for example in antireflection coatings for transmissive optical elements or reflection-increasing coatings for reflective optical elements. Oxidic layers can lengthen the service life of the respective optical element.

Advantageously, the optical element comprises an optically effective coating having at least one first and one second layer on a substrate, the at least one second layer having been produced by a method as described, in particular by means of assistance with electrically neutral particles. In this case, the at least one first layer comprises more neutral particles than if the at least one second layer had been applied without assistance by neutral particles. Since neutral particles have a smaller effective cross section than corresponding charged particles, they can penetrate deeper into surrounding matter.

Advantageously, as an alternative, the optical element comprises an optically effective coating having at least one first and second and third layer on a substrate, the at least one third layer having been produced by a method as described, in particular by means of assistance with neutral particles, and the at least one second layer having been applied without assistance by neutral particles. In this case, the at least one second layer is made thicker than if the at least one third layer had been applied without assistance by neutral particles but with assistance by ions. The second layer can prevent neutral particles with their higher penetration depth than corresponding charged particles from penetrating into the first layer, or can prevent the proportion of neutral particles in the respective first layer from remaining below a defined threshold value.

Other aspects, embodiments, and advantages follow.

### DESCRIPTION OF DRAWINGS

The optical element and method of making the optical element will be explained in greater detail with reference to preferred exemplary embodiments. In this respect:

FIG. 1 shows a schematic illustration of a first arrangement for carrying out a coating method;

FIG. 2 shows a schematic illustration of a second arrangement for carrying out a coating method;

FIG. 3 shows a schematic illustration of a third arrangement for carrying out a coating method;

FIG. 4 shows a schematic illustration of a first component for carrying out a coating method;

FIG. 5A shows a schematic illustration of a second component for carrying out a coating method from the side;

FIG. 5B shows a schematic illustration of a second component for carrying out a coating method from the front;

FIG. 6 shows a schematic illustration of a fourth arrangement for carrying out a coating method

FIG. 7 shows a schematic illustration of a first optical element;

FIG. 8 shows a schematic illustration of a second optical element; and

FIG. 9 shows a schematic illustration of the depth distribution of assisting particles.

### DETAILED DESCRIPTION

The following examples relate—without restricting the generality—to the production of optical elements for the DUV wavelength range, preferably for used wavelengths from the range between 150 nm and 260 nm. This can involve both transmissive optical elements, such as for instance lens elements, and reflective optical elements, such as for instance mirrors. The optical coatings often comprise oxidic and/or fluoridic layers. For example for lens elements for a wavelength of approximately 193 nm, it is possible to provide for instance substrates composed of calcium fluoride having an optical coating comprising oxidic layers, e.g. composed of silicon dioxide or aluminium oxide, and optionally fluoridic layers.

These materials have a low electrical conductivity compared with metallic layers. In conventional coating methods employing ion assistance, the optical elements being produced can quickly become charged during coating, which can adversely influence the coating process. In order to counteract that, measures are proposed here in which the proportion of the assisting particles that is constituted by electrically neutral particles is increased in order to slow down the charging process or to make additional charged particles available in order to at least partly, ideally completely, compensate for the charging process. Ideally, the deposition is also assisted only with electrically neutral particles.

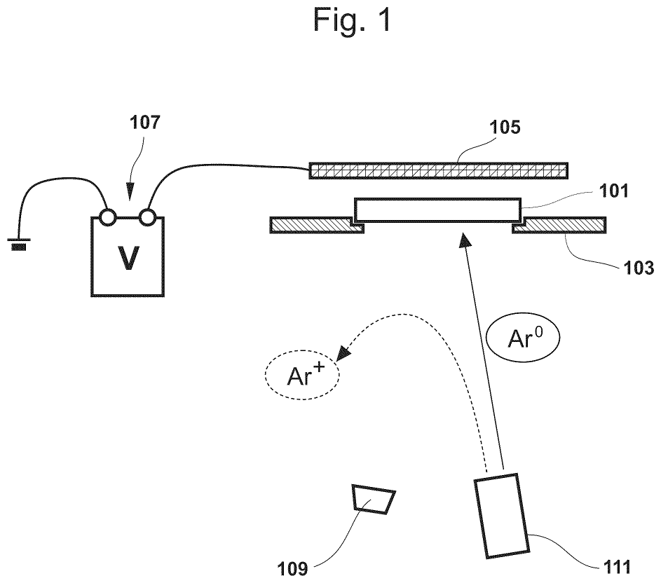

FIG. 1 schematically illustrates a first arrangement for carrying out a method for coating a substrate with at least one coating comprising at least one coating material, the coating material being deposited on the substrate or on a partial coating applied on the substrate, and neutral particles being made available to assist the deposition. For this purpose, a substrate 101 to be coated is mounted in a substrate holder 103. The respective coating material is made available by the material source 109. This can involve in particular an electron beam evaporator or else a thermal evaporator. However, other tried and tested material sources can also be used. Particularly with the use of material sources which emit low-energy particles, it is advantageous additionally to make available higher-energy particles which contribute to the densification of the deposited layer. In the present example, a plasma source 111 is used for this purpose, an argon plasma being generated in this plasma source. Besides argon ions, neutral argon atoms also arise in the process. Only positive argon ions and neutral argon atoms are illustrated in FIG. 1, for the sake of better clarity. Advantageously, already before the filtering by means of an electric field, the proportion of all assistance particles that is constituted by the neutral particles is at least 10%, preferably more than 20%, particularly preferably more than 30%. By means of the electric filtering, the proportion can be increased to more than 80%, preferably more than 90%, particularly preferably more than 95%, and very particularly preferably to almost 100%.

In order as far as possible to prevent charging of the substrate 101, in the example illustrated in FIG. 1, an electrode 105 is arranged on the opposite side of the substrate 101 with respect to the particle flow. By means of a voltage source 107, the electrode 105 is subjected to—in this example—positive potential, and so the positive argon ions are deflected such that they are not incident on the substrate 101 and are filtered out of the particle stream in this way.

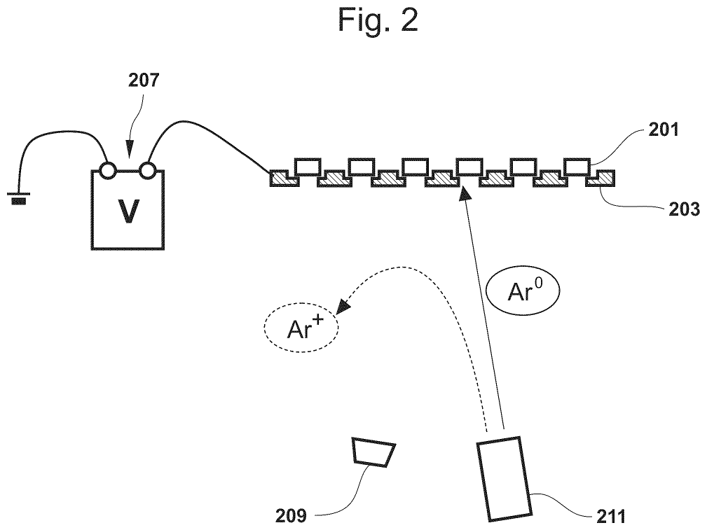

FIG. 2 schematically illustrates a second arrangement for carrying out a method for coating a substrate with at least one coating comprising at least one coating material, the coating material being deposited on the substrate or on a partial coating applied on the substrate, and neutral particles being made available to assist the deposition. In contrast to the example illustrated in FIG. 1, here a plurality of smaller substrates 201 are inserted in a substrate holder 203 in order to coat them in parallel with material from the material source 209 with assistance from argon particles from the plasma source 211. The substrate holder 203 is equally used as an electrode in order to generate a field that repels the positive argon ions. For this purpose, the substrate holder 203 is subjected to a positive potential by means of a voltage source 207.

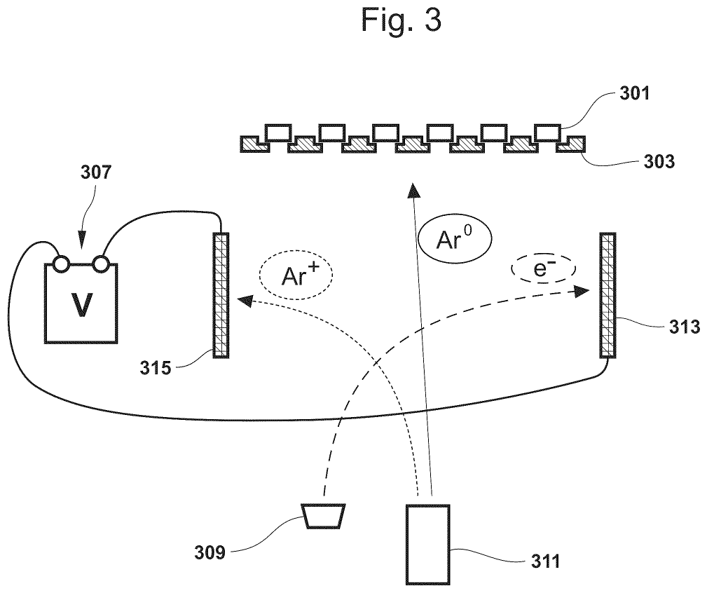

FIG. 3 schematically illustrates a third arrangement for coating with assistance of neutral particles. In the example illustrated here, on the side of a series of substrates 301 facing the particle flow, two electrodes 313, 315 are arranged in the direction of the particle flow. The electrodes 315, 313 are subjected to different potentials by means of a voltage source 307. In the example illustrated, the electrode 315 is at negative potential and attracts the positive argon ions from the plasma source 311. By contrast, the electrode 313 is at positive potential and attracts electrons, which emerge from the material source 309 configured as an electron beam evaporator here, and also negative argon ions (not illustrated). Advantageously, the electrodes 313, 315 are arranged somewhat laterally with respect to the particle flow in order to laterally deflect charged particles. If the positive electrode 313 is omitted in a variant of this set-up, the electrons emerging from the electron beam evaporator 309 can be used for neutralizing the substrates 301.

Spacing and orientation of the electrode or electrodes relative to the particle stream are generally preferably configured so as to avoid secondary sputtering of the electrode(s) and hence contamination of the optical element to be coated.

Alternatively or cumulatively with respect to the coating with assistance of neutral particles as already described, a coating method is also proposed wherein the substrate is impinged on by electrons in a targeted manner in order to at least partly compensate for charging of the coated substrate.

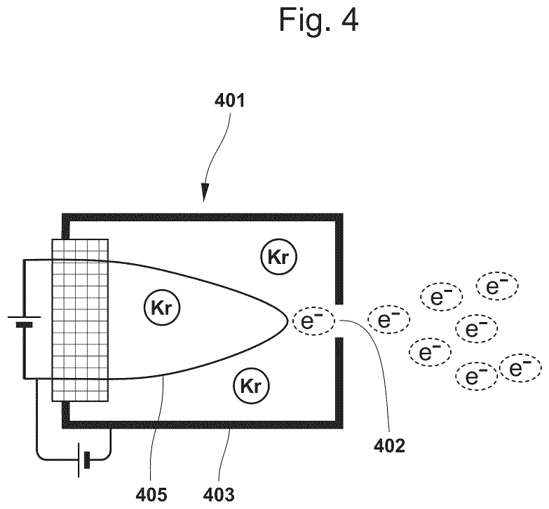

FIG. 4 schematically illustrates a first component for carrying out a coating method wherein the coated substrate is impinged on by electrons in order to compensate for the charging. The component 401 thus serves as a neutralizer, as it were. It emits low-energy electrons and injects them into a particle stream of ions and neutral particles such as may come from an ion source, for example. In a housing 403, said component comprises a glow wire 405, e.g. a singly bent wire, which is heated up by a current and liberates electrons by way of thermionic emission. The wire 405 is subjected to a potential relative to the surrounding housing 403. The housing 403 is additionally filled with an inert gas or gas mixture, preferably noble gas such as argon or krypton, for example. On account of impact ionization with the gas or gas mixture, the number of electrons is significantly increased before they are released from the housing 403 through a small opening 402 therein. In this case, current intensities of a few 100 mA can be attained and thus enough to be able to neutralize customary ion currents during ion-assisted deposition. Components of the design illustrated in FIG. 4 have an operational life of up to a few tens to hundreds of hours.

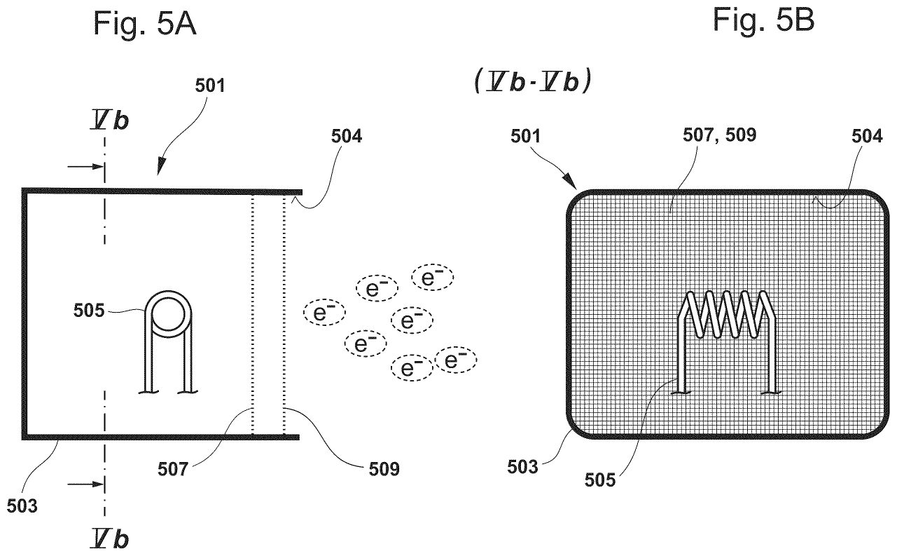

FIGS. 5A and 5B schematically illustrate a second component for carrying out a coating method wherein the coated substrate is impinged on by electrons in order to compensate for the charging. In a housing 503, the component 501 comprises a filament 505, which is multiply wound like an incandescent filament and which generate electrons by way of thermionic emission. At least one grid having a potential difference relative to the filament is arranged at an opening 504 provided on the housing 503. Two grids 507, 509 are provided in the example illustrated here. The grid 507 arranged closer to the filament 505 has a positive potential difference with respect to the filament 505 and acts as a control grid, which removes the emitted electrons from the vicinity of the filament 505. It defines the kinetic energy of the electrons. The grid 509 arranged further away from the filament 505 acts as an extraction grid. A negative voltage is present between the grids 507 and 509 and accelerates the emitted electrons from the region between the two grids 507, 509 towards the outside. In one variant, a further grid can be arranged behind the grids 507, 509 in the direction of movement of the electrons, said further grid being at neutral potential and serving to insulate the acceleration grid 509. In the case of components of the design illustrated in FIGS. 5A and 5B, the entire emission current is generated by thermionic emission, without resorting to impact ionization. They have an operational life of many days to months.

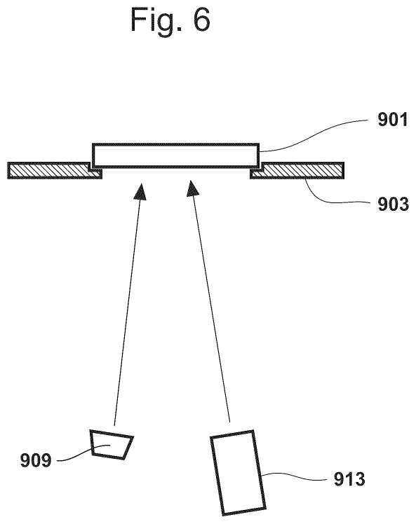

FIG. 6 schematically shows an arrangement for carrying out a coating of a substrate 901 in a substrate holder 903 with an ion source 909 and a neutralizer 913, which is configured like the component 501 from FIGS. 5A and 5B and prevents charging of the substrate 901 or of the (partial) coating already present.

Both components 401 and 501 described by way of example here can be used additionally for coating with assistance by neutral particles.

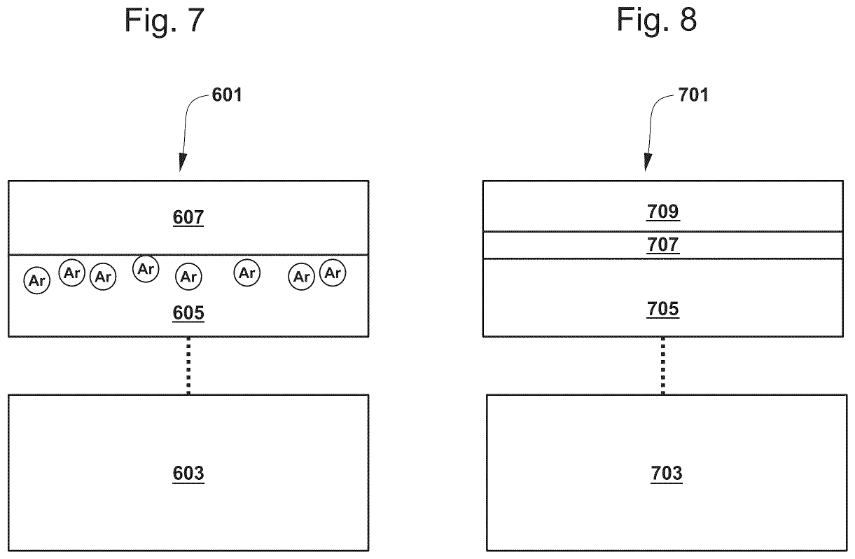

FIG. 7 schematically illustrates a first optical element, in which at least one layer was deposited with assistance by neutral particles. The optical element 601 illustrated by way of example here is designed for used wavelengths in the range of 120 nm to 600 nm, preferably used wavelengths of between 150 nm and 260 nm. An optically effective coating having at least one stack comprising a first layer 605 and a second layer 607 is provided on a substrate 603. One, two, three, four, five, six or more of such stacks comprising first and second layers 605, 607 can be provided as an optically effective coating on the substrate 603, this being indicated by the dotted line. In the present example, the at least one second layer 607 has been applied by means of assistance with neutral particles. This layer here is an oxidic layer which was deposited by means of electron beam evaporation with assistance by neutral particles. During electron beam evaporation, the energy of the coating material is typically a few 100 meV. This results in poor mobility of the particles of the coating material, which in turn leads to relatively porous and rough layers. Therefore, assistance by impingement of neutral particles is particularly advantageous in order simultaneously to densify the deposited layer and to avoid charging of the optical element being produced. Desired densification effects without undesired sputter effects on the deposited layer or areas in the vicinity thereof can be achieved by means of electrically neutral particles having an energy of between 50 eV and 500 eV, preferably 75 eV and 300 eV, particularly preferably 100 eV and 200 eV. On a case-by-case basis, by reducing the angle of incidence of up to 60° with respect to the surface normal, preferably up to 45°, particularly preferably up to 30°, it is possible to lower the sputter rate and to increase the densification of the deposited layer. The dose of the neutral particles should be chosen so as not to be too low, in order to achieve sufficient densification, and not to be too high, in order to avoid excessive and possibly unwanted influencing of the layer structure by the assisting neutral particles. At the same time, the growth rate should be greater than a sputter rate possibly present.

Preferably, gases comprising one or more kinds of noble gas, preferably argon and/or krypton, are used as assistance gas. Depending on the layer to be deposited, it can be advantageous to add to the assistance gas at least one volatile element of the material of the coating to be applied, in order to compensate for the depletion of the layer as a result of the particle bombardment. Oxygen is suitable in the case of oxidic layers. Nitrogen is suitable in the case of nitride-containing layers. The choice of the specific layer material depends on the desired used wavelength or the desired used wavelength range. In this regard, particularly aluminium oxide and silicon dioxide are of interest as oxidic layer materials for instance for the range between 150 nm and 260 nm, in particular around 193 nm. Particularly in the case of silicon dioxide, deposition with assistance with neutral particles can greatly influence the layer structure. As substrates, it is possible to use for example fluorides, in particular calcium fluoride. In the visible wavelength range, for instance, with silicon nitride it is possible to produce anti-scratch layers as proposed here. In principle, it is possible to produce coatings for any desired used wavelengths, from the x-ray and extreme ultraviolet wavelength range, the ultraviolet, the visible or the infrared wavelength range. Besides optical coatings, the coatings can be e.g. protective coatings for mechanical or chemical protection of an optical coating or for protection of the substrate or coatings to withstand mechanical stresses in the optical element.

The electrically neutral particles used for assistance, composed of argon in the present example, have a smaller effective cross section with their surroundings than corresponding ions. This has the effect that the neutral particles can penetrate into the layer material already present on the substrate 603 further than corresponding charged particles. This can be manifested in the fact that the at least one first layer 605 comprises more neutral particles than if the at least one second layer 607 had been applied without assistance by neutral particles, in particular than if it had been applied with corresponding ion assistance.

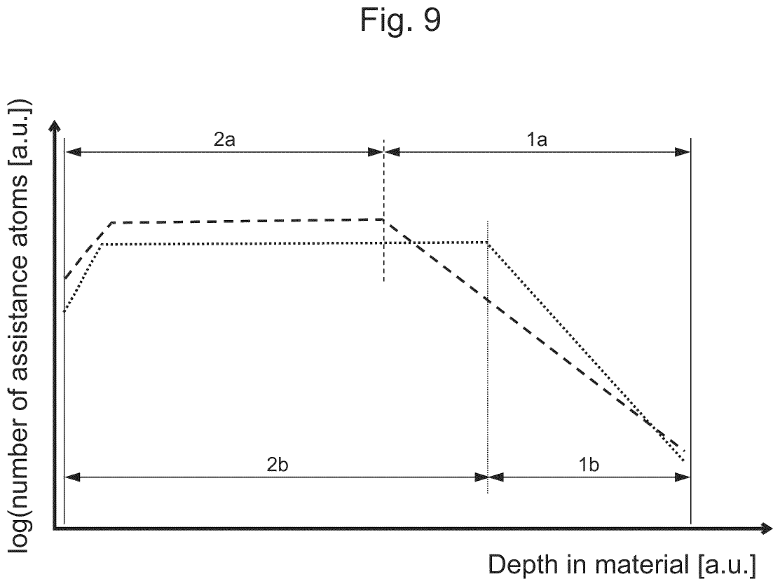

In particular, the penetration depth profile for layers which were deposited with assistance by neutral particles is different from that in the case of layers which were deposited with assistance by ions. This is illustrated schematically in FIG. 9. The number of assistance atoms in arbitrary units, i.e. the number of assisting ions or neutral particles that penetrated during aided or assisted coating, is presented logarithmically as a function of the depth of the material, specifically in the direction of the substrate, likewise in arbitrary units. The penetration depth profile is illustrated for a first layer S1a and an overlying second layer S2a, which was deposited with assistance by neutral particles. This profile is depicted in a dashed manner. A further penetration depth profile is illustrated for a first layer S1b and an overlying second layer S2b, which was deposited with assistance by ions. This profile is depicted in a dotted manner. The number of assistance atoms decreases more rapidly in the layer S1b than in the layer S1a.

If the penetration of assistance particles into the underlying at least one layer is intended to be avoided, a construction of an optical element as in FIG. 8 can be advantageous. The optical element 701 differs from that explained in association with FIG. 6 to the effect that on the substrate 703 between the arbitrarily applied at least one first layer 705 and the at least one third layer 709 applied with assistance from neutral particles, at least one second layer 707 applied without assistance is provided, which is composed of the same coating material as the third layer 709 applied with assistance and serves as an intermediate layer. Since the second layer 707 is applied without assistance, it differs from the third layer 709 by virtue of a lower density and it traps the neutral particles that penetrate deeper into the already present partial coating during the assisted application of the third layer 709. In order that the proportion of neutral particles in the first layer 705 is negligible, however, it is necessary—owing to the smaller effective cross section of the neutral particles with the surrounding material in comparison with charged particles—for the second layer 707 to be thicker than if the at least one third layer 709 had been applied without assistance by neutral particles, in particular than if it had been applied with corresponding ion assistance.

It should be pointed out that deposition by means of electron beam evaporation was discussed in the present example. It is also possible, however, to use other tried and tested chemical and/or physical vapour deposition methods, in particular thermal evaporation.

The optical elements produced as proposed can be used for example in the UV lithography of semiconductor elements or in optical systems for inspecting wafers, imaging masks or optical elements.

Other embodiments are within the scope of the following claims.

### REFERENCE SIGNS

101 Substrate
103 Substrate holder
105 Electrode
107 Voltage source
109 Material source
111 Plasma source
201 Substrate
203 Substrate holder
207 Voltage source
209 Material source
211 Plasma source
301 Substrate
303 Substrate holder
307 Voltage source
309 Material source
311 Plasma source
313 Electrode
315 Electrode
401 Component
402 Opening
403 Housing
405 Glow wire
501 Component
503 Housing
504 Opening
505 Filament
507 Grid
509 Grid
601 Optical element
603 Substrate
605 First layer
607 Second layer
701 Optical element
703 Substrate
705 First layer
707 Second layer
709 Third layer
901 Substrate
903 Substrate holder
909 Ion source
913 Neutralizer

What is claimed is:

1. A method for coating a substrate with at least one coating having at least one coating material, the method comprising depositing the coating material on the substrate or on a partial coating applied on the substrate, wherein electrically neutral particles are made available to assist the deposition and wherein at least one electrode is arranged in the direction of a particle flow of the coating material on the side of the substrate facing the particle flow.

2. The method of claim 1, wherein the neutral particles having an energy of between 50 eV and 500 eV, preferably 75 eV and 300 eV, particularly preferably 100 eV and 200 eV, are made available.

3. The method of claim 1, wherein neutral particles are made available at an angle of incidence of up to 60° with respect to the surface normal, preferably up to 45°, particularly preferably up to 30°.

4. The method of claim 1, wherein one or more noble gases are used as an assistance gas for the deposition.

5. The method of claim 4, wherein at least one volatile element of the material of the coating to be applied is added to the assistance gas.

6. The method of claim 1, wherein a conductive substrate is coated and a voltage is applied to the substrate.

7. The method of claim 1, wherein another electrode is arranged on the opposite side of the substrate with respect to a particle flow.

8. A method for coating a substrate with at least one coating having at least one coating material, the method comprising depositing the coating material on the substrate or on a partial coating applied on the substrate, wherein the substrate is impinged on by electrons by a filament arranged in a housing and at least one grid having a potential difference relative to the filament at an opening provided on the housing.

9. The method of claim 1, wherein the deposition is carried out by means of electron beam evaporation or thermal evaporation.

10. An optical element having at least one layer which was applied by means of the method of claim 1.

11. The optical element of claim 10, wherein the at least one layer comprises at least one oxidic layer.

12. The optical element of claim 10, wherein the at least one layer comprises at least one first and one second layer on a substrate, the at least one second layer having been produced by the method of claim 1, wherein the at least first layer comprises more electrically neutral particles than what it would have had if the at least one second layer had been applied without assistance by neutral particles.

13. The optical element of claim 10, wherein the at least one layer comprises at least one first and second and third layer on a substrate, the at least one third layer having been produced by a method of claim 1, and the at least one second layer having been applied without assistance by electrically neutral particles, and wherein the at least one second layer is thicker than it would have been if the at least one third layer had been applied without assistance by neutral particles but with assistance by charged particles.

14. The method of claim 8, wherein the deposition is carried out by means of electron beam evaporation or thermal evaporation.

15. An optical element having at least one layer which was applied by means of the method of claim 8.

16. The optical element of claim 15, wherein the at least one layer comprises at least one oxidic layer.

17. The optical element of claim 15, wherein the at least one layer comprises at least one first and one second layer on a substrate, the at least one second layer having been produced by the method of claim 1, wherein the at least first layer comprises more electrically neutral particles than what it would have had if the at least one second layer had been applied without assistance by neutral particles.

18. The optical element of claim 15, wherein the at least one layer comprises at least one first and second and third layer on a substrate, the at least one third layer having been produced by a method of claim 1, and the at least one second layer having been applied without assistance by electrically neutral particles, and wherein the at least one second layer is thicker than it would have been if the at least one third layer had been applied without assistance by neutral particles but with assistance by charged particles.

19. The method of claim 2, wherein neutral particles are made available at an angle of incidence of up to 60° with respect to the surface normal, preferably up to 45°, particularly preferably up to 30°.

20. The method of claim 19, wherein one or more noble gases are used as an assistance gas for the deposition and wherein at least one volatile element of the material of the coating to be applied is added to the assistance gas.
